(19) United States
(12) Patent Application Publication
(10) Pub. No.: US 2021/0028165 A1
(43) Pub. Date: Jan. 28, 2021

(54) Capacitor Structure

(71) Applicant: Realtek Semiconductor Corp., HsinChu (TW)

(72) Inventors: Sz-Ying Yu, Hsinchu County (TW); Jui-Yu Chang, Hsinchu City (TW); Chien-Wen Chen, Hsinchu City (TW)

(21) Appl. No.: 16/905,936

(22) Filed: Jun. 19, 2020

(30) Foreign Application Priority Data
Jul. 23, 2019 (TW) 108126042

(51) Int. Cl. H01L 27/06; H01L 23/522

(52) U.S. Cl. CPC H01L 27/0688; H01L 23/5223; H01L 23/5226

(57) ABSTRACT

The present invention provides a capacitor structure including a metal oxide semiconductor (MOS) capacitor and a metal oxide metal (MOM) capacitor. A gate electrode, a source electrode and a drain electrode of the MOS capacitor have a first finger-shaped structure implemented by a first metal layer. The MOM capacitor comprises a second finger-shaped structure implemented by a second metal layer. The second metal layer is adjacent to the first metal layer in a vertical direction.

### BACKGROUND OF THE INVENTION

### 1. Field of the Invention

The invention relates to a capacitor structure, more particularly to a capacitor structure combining a metal-oxide-semiconductor (MOS) capacitor and a metal-oxide-metal (MOM) capacitor.

### 2. Description of the Prior Art

In the layout of an integrated circuit, a capacitor usually occupies a relatively large area, thus affecting the manufacturing cost of the chip. Therefore, in order to have a high capacitance in a limited space, MOM capacitors are usually used in the prior art to achieve this purpose. However, the conventional design cannot fully utilize each metal layer. Therefore, the conventional design cannot obtain an optimal capacitance.

### SUMMARY OF THE INVENTION

An objective of the invention is to provide a capacitor structure combining a MOS capacitor and a MOM capacitor. In the proposed capacitor structure, each metal layer can be fully utilized, such that the highest capacitance can be achieved in the limited space and the above-mentioned problem in the conventional design can be solved.

An embodiment of the invention provides a capacitor structure comprising a metal oxide semiconductor (MOS) capacitor and a metal oxide metal (MOM) capacitor. A gate electrode, a source electrode and a drain electrode of the MOS capacitor have a first finger-shaped structure implemented by a first metal layer. The MOM capacitor comprises a second finger-shaped structure implemented by a second metal layer. The second metal layer is adjacent to the first metal layer in a vertical direction.

Another embodiment of the invention provides a capacitor structure comprising anion doped substrate, a first metal layer for implementing a first finger-shaped structure on the ion doped substrate and a second metal layer for implementing a second finger-shaped structure. The second metal layer is adjacent to the first metal layer in a vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a capacitor structure according to an embodiment of the invention.

FIG. 2 is a layout diagram showing the first metal layer of the capacitor structure according to an embodiment of the invention.

FIG. 3 is a layout diagram showing the second metal layer of the capacitor structure according to an embodiment of the invention.

FIG. 4 is a layout diagram showing the third metal layer of the capacitor structure according to an embodiment of the invention.

FIG. 5 is a layout diagram showing the top view of the capacitor structure according to an embodiment of the invention.

FIG. 6 is a cross-sectional view of the capacitor structure according to an embodiment of the invention.

FIG. 7 is a schematic diagram of the capacitances of the capacitor structure in FIG. 6.

### DETAILED DESCRIPTION

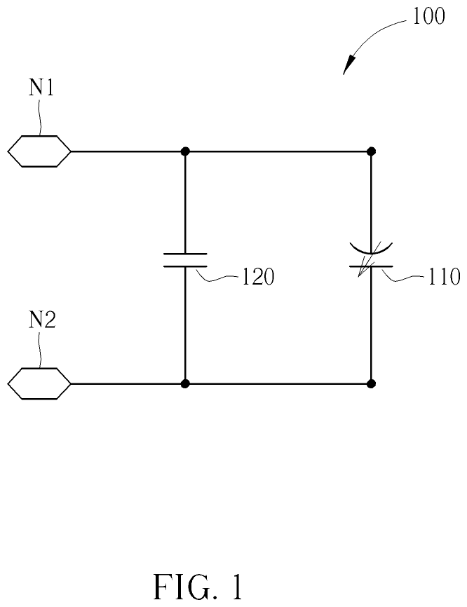

FIG. 1 is a schematic diagram of a capacitor structure 100 according to an embodiment of the invention. As shown in FIG. 1, the capacitor structure 100 may comprise a metal oxide semiconductor (MOS) capacitor 110, a metal oxide metal (MOM) capacitor 120 and two terminals N1 and N2. The MOS capacitor 110 is a capacitor implemented by a Metal-Oxide-Semiconductor Field-Effect Transistor (MOSFET). In this embodiment, the MOS capacitor 110 is a MOS varactor. In the capacitor structure 100, when a voltage across the terminals N1 and N2 is higher than a threshold, the MOS capacitor 110 has a better capacitance. In addition, the MOM capacitor 120 provides additional capacitance in the remaining available metal layer, thus allowing the capacitor structure 100 to have an optimum capacitance in a limited space.

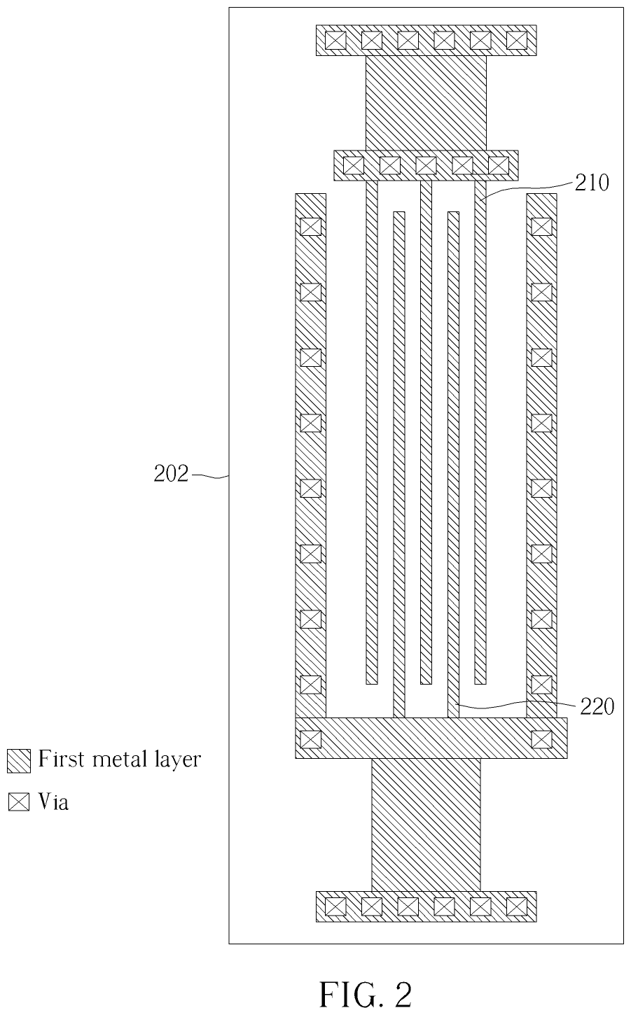

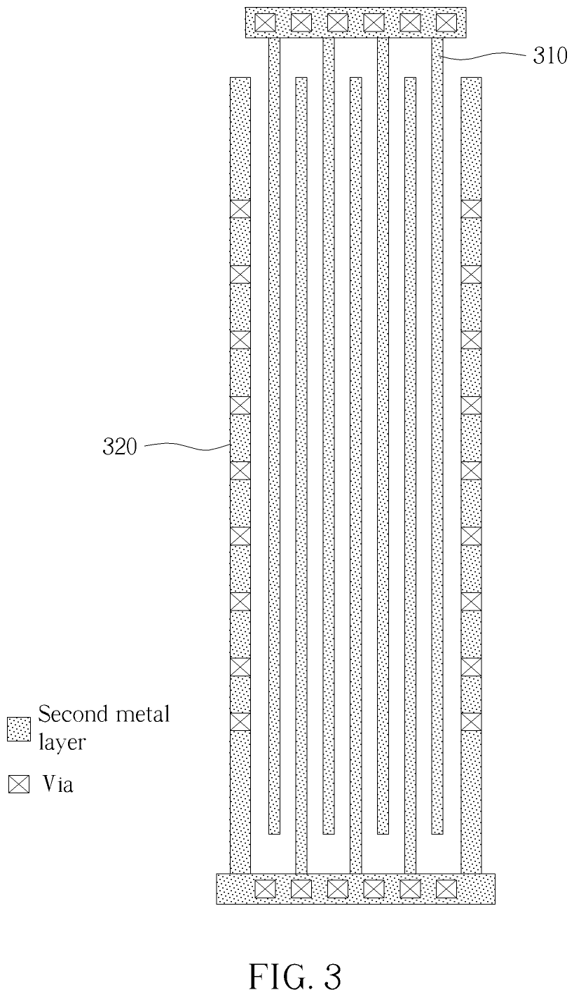

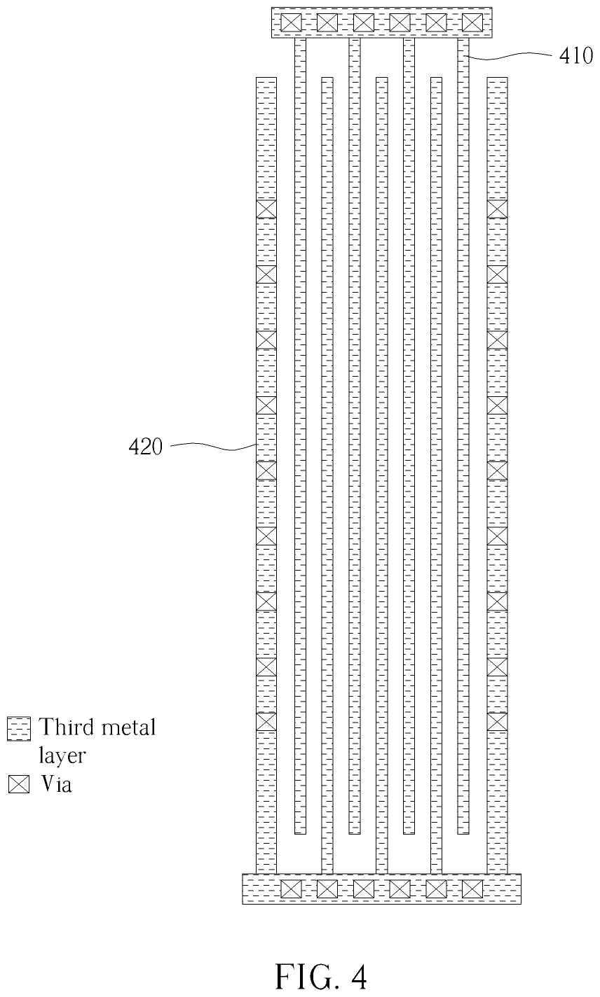

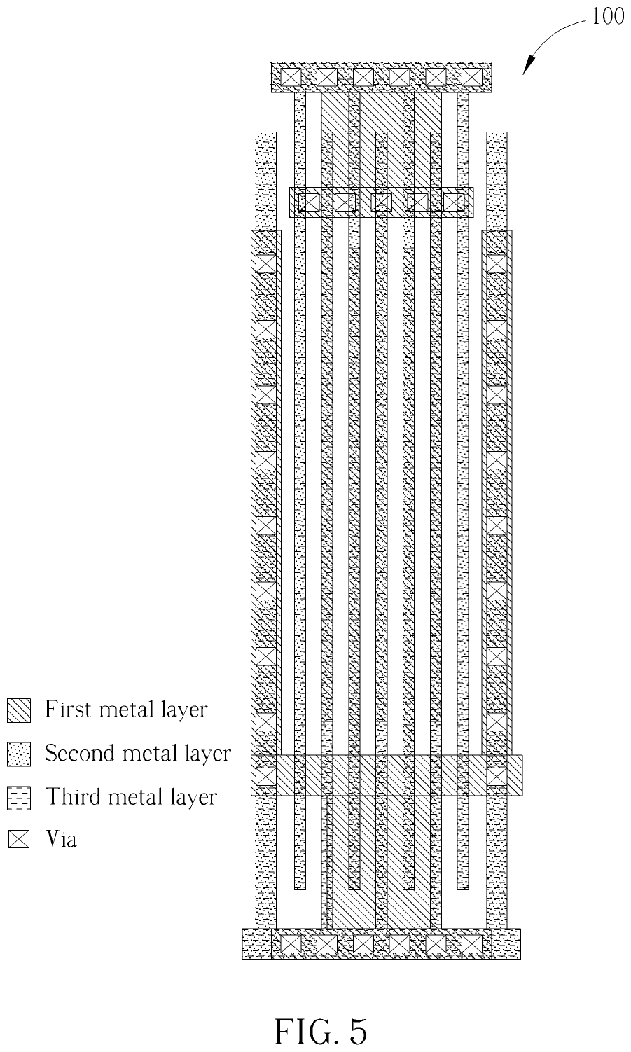

For more details, reference may be made from FIG. 2 to FIG. 5. FIG. 2 is a layout diagram showing the first metal layer of the capacitor structure 100 according to an embodiment of the invention. FIG. 3 is a layout diagram showing the second metal layer of the capacitor structure 100 according to an embodiment of the invention. FIG. 4 is a layout diagram showing the third metal layer of the capacitor structure 100 according to an embodiment of the invention. FIG. 5 is a layout diagram showing the top view of the capacitor structure 100 according to an embodiment of the invention. In FIG. 2, the MOS capacitor 110 may be implemented by the first metal layer, where the gate electrode, the source electrode and the drain electrode of the MOS capacitor 110 are the first finger-shaped structure implemented by the first metal layer. To be more specific, the first finger-shaped structure shown in FIG. 2 comprises a first portion 210 and a second portion 220, where the first portion 210 and the second portion 220 of the first finger-shaped structure are not connected with each other (that is, electrically isolated). The first portion 210 of the first finger-shaped structure is the gate electrode of the MOS capacitor 110 and the second portion 220 of the first finger-shaped structure is the source electrode and the drain electrode of the MOS capacitor 110. The first portion 210 and the second portion 220 are arranged in an interleaved manner. In this embodiment, the first portion 210 is electrically connected to the terminal N1 and the second portion 220 is electrically connected to the terminal N2, thereby forming the MOS capacitor 110. For example, the terminal N1 is electrically connected to the power node and the terminal N2 is electrically connected to the ground node. It should be noted that the second portion 220 being as the source electrode and the drain electrode of the MOS capacitor 110 may be implemented on an ion doped substrate 202 (for example, the region under the second portion 220 may be a heavily doped region), and the first portion 210 being as the gate electrode of the MOS capacitor 110 may be formed on the substrate 202 via an oxide layer. Depending on the design requirements, the substrate 202 may be electrically connected to one of the terminals N1 and N2. Since the structural of the substrate 202 is not the focus of the invention, details are not described herein for brevity.

As shown in FIG. 3, the MOM capacitor 120 may comprise a second finger-shaped structure implemented by the second metal layer. The second metal layer is adjacent to the first metal layer in a vertical direction. That is, only an isolation layer is disposed between the first metal layer and the second metal layer in the vertical direction, and there is no other metal layer disposed between the first metal layer and the second metal layer. In this embodiment, the second metal layer is stacked vertically above the first metal layer. However, the invention should not be limited thereto. The second finger-shaped structure shown in FIG. 3 comprises a first portion 310 and a second portion 320, where the first portion 310 and the second portion 320 of the second finger-shaped structure are not connected with each other (that is, electrically isolated). In this embodiment, the first portion 310 of the second finger-shaped structure and the first portion 210 of the first finger-shaped structure are substantially overlapped. The first portion 310 of the second finger-shaped structure and the first portion 210 of the first finger-shaped structure are electrically connected with each other through a plurality of vias and are electrically connected to the terminal N1. The second portion 220 of the first finger-shaped structure and the second portion 320 of the second finger-shaped structure are substantially overlapped. The second portion 220 of the first finger-shaped structure and the second portion 320 of the second finger-shaped structure are electrically connected with each other through a plurality of vias and are electrically connected to the terminal N2. In addition, in an embodiment of the invention, as can be seen from the top view, the second finger-shaped structure is longer than the first finger-shaped structure.

As shown in FIG. 4, the MOM capacitor 120 may comprise a third finger-shaped structure implemented by the third metal layer. The third metal layer is adjacent to the second metal layer in the vertical direction. That is, only an isolation layer is disposed between the second metal layer and the third metal layer in the vertical direction, and there is no other metal layer disposed between the second metal layer and the third metal layer. In this embodiment, the third metal layer is stacked vertically above the second metal layer. However, the invention should not be limited thereto. The third finger-shaped structure shown in FIG. 4 comprises a first portion 410 and a second portion 420, where the first portion 410 and the second portion 420 of the third finger-shaped structure are not connected with each other (that is, electrically isolated). In this embodiment, the first portion 410 of the third finger-shaped structure and the first portion 210 of the first finger-shaped structure are substantially overlapped. The first portion 410 of the third finger-shaped structure, the first portion 310 of the second finger-shaped structure and the first portion 210 of the first finger-shaped are electrically connected with each other through a plurality of vias and are electrically connected to the terminal N1. The second portion 420 of the third finger-shaped structure and the second portion 220 of the first finger-shaped structure are substantially overlapped. The second portion 420 of the third finger-shaped structure, the second portion 320 of the second finger-shaped structure and the second portion 220 of the first finger-shaped structure are electrically connected with each other through a plurality of vias and are electrically connected to the terminal N2. In addition, in an embodiment of the invention, as can be seen from the top view, the third finger-shaped structure is longer than the first finger-shaped structure.

In the embodiments shown from FIG. 2 to FIG. 5, the capacitor structure 100 comprises only three metal layers. However, it should be noted that the invention is limited thereto. In other embodiments of the invention, the MOM capacitor 120 in the capacitor structure 100 may also comprise other finger-shaped structure implemented by other metal layer, such as a fourth metal layer or other metal layer adjacent to the third metal layer in the vertical direction, so as to increase the capacitance of the MOM capacitor 120.

In the embodiment shown in FIG. 5, the second finger-shaped structure implemented by the second metal layer and the third finger-shaped structure implemented by the third metal layer may substantially overlap the first finger-shaped structure implemented by the first metal layer. However, the invention should not be limited thereto. In other embodiments of the invention, there may be only a portion of the second finger-shaped structure implemented by the second metal layer overlaps the first finger-shaped structure implemented by the first metal layer, and there may be only a portion of the third finger-shaped structure implemented by the third metal layer overlaps the first finger-shaped structure implemented by the first metal layer. These modifications/alterations should all be within the scope of the present invention.

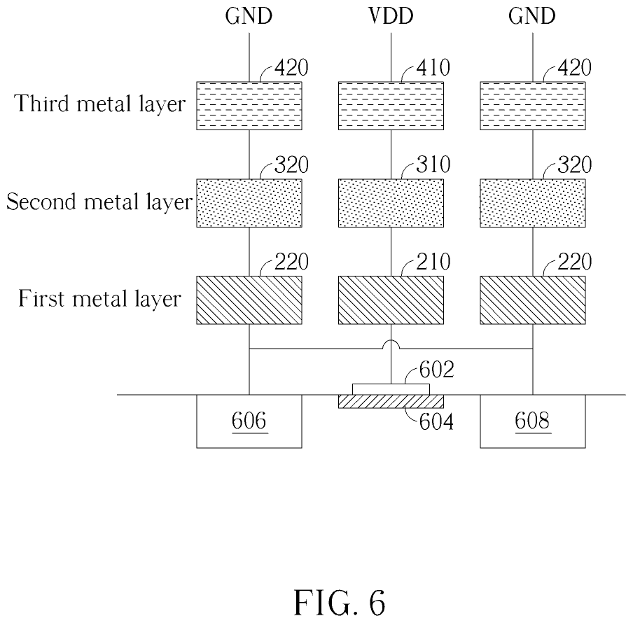

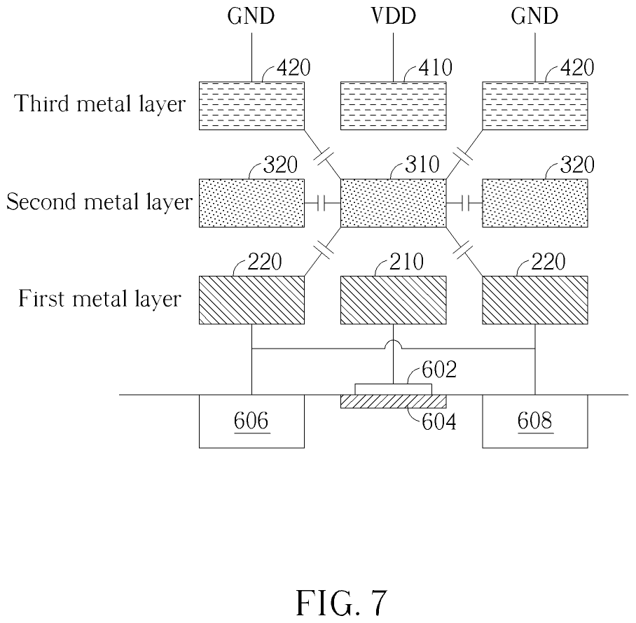

FIG. 6 is a cross-sectional view of the capacitor structure 100 according to an embodiment of the invention. The numbers 602 and 604 labeled in FIG. 6 represent the gate electrode and the oxide layer, respectively. The numbers 606 and 608 labeled in FIG. 6 represent the heavily doped region. In FIG. 6, the gate electrode 602, the heavily doped region 606 and the heavily doped region 608 are respectively connected to the first portion 210 and the second portion 220 of the first finger-shaped structure through a connecting element (for example, through a contact). The first finger-shaped structure is implemented by the first metal layer. The first portion 210 is connected to the first portion 310 of the second finger-shaped structure implemented by the second metal layer and the first portion 410 of the third finger-shaped structure implemented by the third metal layer through a via. The second portion 220 is connected to the second portion 320 of the second finger-shaped structure implemented by the second metal layer and the second portion 420 of the third finger-shaped structure implemented by the third metal layer through another via. In an embodiment of the invention, the first portion 210/310/410 is connected to the power node (VDD) and the second portion 220/320/420 is connected to the ground node (GND). In the cross-sectional view shown in FIG. 6, there is no capacitance between metal layers that are adjacent to each other in the vertical direction. As shown in FIG. 7, there is no capacitance between the first portions 210, 310 and 410, and there is no capacitance between the second portions 220, 320 and 420. Taking the first portion 310 as an example, multi-directional capacitances can be generated between the first portion 310 and the second portion 220 and between the first portion 310 and the second portion 420. In this manner, the capacitance of the capacitor structure 100 can be effectively increased.

In the conventional capacitor structure comprising the MOS capacitor and the MOM capacitor, since the second metal layer and the third metal layer are utilized for connecting the electrode of the MOS capacitor or for connecting the electrode of the MOS capacitor and the MOM capacitor, the second metal layer and the third metal layer will not be designed to have the finger-shaped structure as shown in FIG. 3 and FIG. 4 when the problem that the second metal layer and the third metal layer have a plurality of connecting lines is considered, and the MOM capacitor has to be implemented by other metal layer.

On the contrary, in the proposed capacitor structure 100 shown in FIG. 5, the first metal layer of the MOS capacitor 110 is designed to have similar finger-shaped structure as the metal layers of the MOM capacitor 120, and the first finger-shaped structure implemented by the first metal layer is divided into the first portion 210 and the second portion 220 that are electrically isolated. The first portion 210 is utilized as the gate electrode of the MOS capacitor 110 and the second portion 220 is utilized as the source electrode and the drain electrode of the MOS capacitor 110. Therefore, the second metal layer and the third metal layer can be utilized to form the MOM capacitor 120. In addition, since the MOM capacitor 120 implemented by the second metal layer and the third metal layer has the finger-shaped structure that is similar to the first metal layer, the capacitance between the MOM capacitor 120 and the MOS capacitor 110 can be greatly increased, thereby the overall capacitance of the capacitor structure 100 can be greatly increased. In a practical simulation example, it is assumed that a conventional capacitor structure having a MOS capacitor and a MOM capacitor has a capacitance of 0.32 pf (pico-farad) in an area of 133 μm², in the embodiment of the invention, for the capacitor structure 100 having the same area can have a capacitance of 0.46 pf, which is about 40% more than the conventional capacitor structure. Therefore, it is indeed helpful for the proposed capacitor structure to obtain the maximum capacitance value in the case where the wafer or chip area is shrinking day by day.

In summary, in the proposed capacitor structure comprising the MOS capacitor and the MOM capacitor, the MOM capacitor is formed by the second metal layer and the third metal layer, and the MOS capacitor and the MOM capacitor have similar finger-shaped structure. In this manner, each metal layer can be fully utilized, so that the chip has the highest capacitance in a limited space.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor structure, comprising:
a metal oxide semiconductor (MOS) capacitor, wherein a gate electrode, a source electrode and a drain electrode of the MOS capacitor have a first finger-shaped structure implemented by a first metal layer; and
a metal oxide metal (MOM) capacitor, wherein the MOM capacitor comprises at least a second finger-shaped structure implemented by a second metal layer, and the second metal layer is adjacent to the first metal layer in a vertical direction.

2. The capacitor structure of claim 1, wherein the second finger-shaped structure substantially overlaps the first finger-shaped structure.

3. The capacitor structure of claim 1, wherein the second finger-shaped structure is longer than the first finger-shaped structure.

4. The capacitor structure of claim 1, wherein the MOM capacitor further comprises a third finger-shaped structure implemented by a third metal layer, and the third metal layer is adjacent to the second metal layer in the vertical direction.

5. The capacitor structure of claim 4, wherein the second finger-shaped structure and the third finger-shaped structure substantially overlap the first finger-shaped structure.

6. The capacitor structure of claim 1, wherein the first finger-shaped structure comprises a first portion and a second portion, the first portion and the second portion of the first finger-shaped structure are not connected with each other, the second finger-shaped structure comprises a first portion and a second portion, the first portion and the second portion of the second finger-shaped structure are not connected with each other, the first portion of the first finger-shaped structure and the first portion of the second finger-shaped structure are electrically connected with each other through at least a first via as a first terminal of the capacitor structure, and the second portion of the first finger-shaped structure and the second portion of the second finger-shaped structure are electrically connected with each other through at least a second via as a second terminal of the capacitor structure.

7. The capacitor structure of claim 6, wherein the first portion of the first finger-shaped structure is the gate electrode of the MOS capacitor and the second portion of the first finger-shaped structure is the source electrode and the drain electrode of the MOS capacitor.

8. The capacitor structure of claim 6, wherein the MOM capacitor further comprises a third finger-shaped structure implemented by a third metal layer and the third metal layer is adjacent to the second metal layer in the vertical direction, the third finger-shaped structure comprises a first portion and a second portion, the first portion and the second portion of the third finger-shaped structure are not connected with each other, the first portion of the first finger-shaped structure, the first portion of the second finger-shaped structure and the first portion of the third finger-shaped structure are electrically connected with each other through at least the first via as the first terminal of the capacitor structure, and the second portion of the first finger-shaped structure, the second portion of the second finger-shaped structure and the second portion of the third finger-shaped structure are electrically connected with each other through at least the second via as the second terminal of the capacitor structure.

9. The capacitor structure of claim 1, wherein the gate electrode, the source electrode and the drain electrode of the MOS capacitor are electrically connected to the first metal layer through a connecting element, and the first metal layer is a metal layer on a same plane.

10. The capacitor structure of claim 1, wherein there is no capacitance between a portion of the first metal layer and a portion of the second metal layer, where the portion of the first metal layer is adjacent to the portion of the second metal layer in the vertical direction.

11. A capacitor structure, comprising:
an ion doped substrate;
a first metal layer, for implementing a first finger-shaped structure on the ion doped substrate; and
a second metal layer, for implementing a second finger-shaped structure, wherein the second metal layer is adjacent to the first metal layer in a vertical direction.

12. The capacitor structure of claim 11, wherein the first finger-shaped structure and the ion doped substrate form a metal oxide semiconductor (MOS) capacitor.

13. The capacitor structure of claim 12, wherein a gate electrode, a source electrode and a drain electrode of the MOS capacitor are electrically connected to the first metal layer through a connecting element, and the first metal layer is a metal layer on a same plane.

14. The capacitor structure of claim 12, wherein the first finger-shaped structure comprises a first portion and a second portion, the first portion and the second portion of the first finger-shaped structure are not connected with each other, the first portion of the first finger-shaped structure is a gate electrode of the MOS capacitor, and the second portion of the first finger-shaped structure is a source electrode and a drain electrode of the MOS capacitor.

15. The capacitor structure of claim 14, wherein the second finger-shaped structure comprises a first portion and a second portion, the first portion and the second portion of the second finger-shaped structure are not connected with each other, the first portion of the first finger-shaped structure and the first portion of the second finger-shaped structure are electrically connected with each other through at least a first via as a first terminal of the capacitor structure, and the second portion of the first finger-shaped structure and the second portion of the second finger-shaped structure are electrically connected with each other through at least a second via as a second terminal of the capacitor structure.

16. The capacitor structure of claim 11, wherein the second finger-shaped structure substantially overlaps the first finger-shaped structure.

17. The capacitor structure of claim 11, wherein the second finger-shaped structure is longer than the first finger-shaped structure.

18. The capacitor structure of claim 11, further comprising:
a third metal layer, for implementing a third finger-shaped structure, wherein the third metal layer is adjacent to the second metal layer in the vertical direction.

19. The capacitor structure of claim 18, wherein the second finger-shaped structure and the third finger-shaped structure substantially overlap the first finger-shaped structure.

20. The capacitor structure of claim 11, wherein there is no capacitance between a portion of the first metal layer and a portion of the second metal layer, where the portion of the first metal layer is adjacent to the portion of the second metal layer in the vertical direction.
